(19) United States
(12) Patent Application Publication
(10) Pub. No.: US 2013/0340943 A1
(43) Pub. Date: Dec. 26, 2013

(54) BONDING APPARATUS

(71) Applicant: SHIBUYA KOGYO CO., LTD., Kanazawa-shi (JP)

(72) Inventors: Tadashi YOSHIDA, Ishikawa-ken (JP); Eiji TANAKA, Ishikawa-ken (JP)

(21) Appl. No.: 13/924,937

(22) Filed: Jun. 24, 2013

(30) Foreign Application Priority Data
Jun. 26, 2012 (JP) 2012-142946

(51) Int. Cl. H01L 23/00

(52) U.S. Cl. CPC H01L 24/74
USPC 156/380.9; 156/498

(57) ABSTRACT

A bonding apparatus includes: a bonding head including a bonding tool, on which a suction surface for a chip is formed, and a heating unit; a chip supply unit; a bonding stage on which a substrate is arranged; a head movement unit configured to move the bonding head between a chip supply position by the chip supply unit and a bonding position on the bonding stage; and a cooling unit configured to cool the bonding tool. The bonding tool is configured such that the chip is supplied at the chip supply position, then is heated and bonded on the substrate at the bonding position, and is then cooled by the cooling unit. The cooling is performed by making the suction surface come in contact with a cooling surface of the cooling unit.

### CROSS-REFERENCE TO RELATED APPLICATION

This application claims priority from Japanese Patent Application No. 2012-142946 filed on Jun. 26, 2012, the entire subject-matter of which is incorporated herein by reference.

### BACKGROUND OF THE INVENTION

1. Field of Invention

The present invention relates to a bonding apparatus configured to bond a chip on a substrate, and more particularly to a cooling technology of a bonding tool in a bonding apparatus.

2. Description of Related Art

There has been proposed an apparatus which maintains a chip with a bonding tool, heats the bonding tool, and bonds the chip on a substrate. In this kind of bonding apparatus, it is necessary to lower the temperature of the bonding tool that maintains the chip to a predetermined temperature in order to reduce an influence exerted on the chip until a next chip is maintained after the bonding of the chip on the substrate is performed.

In a case of a solder bump joining type bonding, it is necessary to lower the temperature of the bonding tool below the solder melting temperature of about 200° C., and preferably to about 150° C. In a case of a joining method with thermosetting resin adhesives, it is necessary to lower the temperature of the bonding tool below 100° C. to 180° C. that is the hardening start temperature of the thermosetting resin, and preferably to a temperature that is almost a room temperature (about 50° C.).

A related-art technology for lowering the temperature of a bonding tool to a predetermined temperature is shown in Japanese Patent No. 3172942 and JP-A-2007-329305. The related-art technology uses cooling with gas. In a case where the gas is air, the thermal conductivity is maximally 40 W/m·K, and the cooling time is delayed to cause a problem that the bonding work time gets longer.

### SUMMARY OF THE INVENTION

Illustrative aspects of the present invention shorten the bonding work time by realizing cooling at higher speed than the cooling with the gas through performing the cooling in a state where a suction surface of a chip of a bonding tool comes in direct contact with a cooling surface of a cooling unit.

According to a first aspect of the invention, there is provided a bonding apparatus comprising: a bonding head comprising a bonding tool, on which a suction surface for sucking and maintaining a chip is formed, and a heating unit; a chip supply unit configured to supply the chip to the bonding tool; a bonding stage on which a substrate is arranged; a head movement unit configured to move the bonding head between a chip supply position by the chip supply unit and a bonding position on the bonding stage; and a cooling unit configured to cool the bonding tool, wherein the bonding apparatus is configured to: supply the chip from the chip supply position to the bonding tool; perform bonding of the chip on the substrate through heating the chip in the bonding position; and then cool the bonding tool by the cooling unit, wherein the cooling unit has a cooling surface configured to come in contact with the suction surface of the bonding tool, and wherein the cooling unit is configured to cool the bonding tool through making the cooling surface come in contact with the suction surface.

According to a second aspect of the invention, in the first aspect, the cooling unit comprises a Peltier element for cooling the cooling surface and is configured to compulsorily cool the bonding tool.

According to a third aspect of the invention, in the first or second aspect, the cooling unit comprises a gas supply unit for supplying a dew condensation prevention gas and is configured to make the suction surface come in contact with the cooling surface in a dew condensation prevention gas atmosphere.

According to a fourth aspect of the invention, in any one of the first to third aspects, the heating unit comprises: a laser resonator configured to oscillate laser beam; and a light guide unit configured to guide the laser beam generated by the laser resonator into the bonding head. The heating unit is configured to: directly heat the chip by the laser beam that is oscillated from the laser resonator and is guided into the bonding head by the light guide unit; or indirectly heat the chip through heating the bonding tool by the laser beam.

According to the first aspect of the invention, the bonding tool is cooled by making the cooling surface of the cooling unit come in contact with the suction surface of the bonding tool. Since the cooling is performed through contact with the thing that has better heat conductivity than the gas, high-speed cooling at a low temperature level can be performed, and thus the cooling time can be shortened. As a result, since the processing time of the bonding apparatus is shortened, the productivity of the bonding apparatus can be increased.

According to the second aspect of the invention, since the bonding tool is compulsorily cooled by using the Peltier element that cools the cooling surface as the cooling unit, the cooling efficiency can be increased, and thus the cooling time can be further shortened. As a result, since the processing time of the bonding apparatus can be further shortened, the productivity of the bonding apparatus can be further increased.

According to the third aspect of the invention, by making the suction surface and the cooling surface come in contact with each other in a dew condensation prevention atmosphere, the dew condensation on the cooling surface can be prevented, and thus the problem of the bonding due to the dew condensation can be solved.

According to the fourth aspect of the invention, since the chip is directly heated by the laser beam that is oscillated by the laser resonator and is guided into the bonding head by the light guide unit, or the chip is indirectly heated through heating of the bonding tool, the volume of the target for cooling, e.g., the thermal capacity, can be reduced, and as a result, the cooling time can be shortened.

### BRIEF DESCRIPTION OF THE DRAWINGS

FIG. 1 is a schematic explanatory front view of a bonding apparatus;

FIG. 2 is a schematic explanatory plan view of the bonding apparatus; and

FIG. 3 is a schematic explanatory view of an interior of a front end of a bonding head.

### DETAILED DESCRIPTION

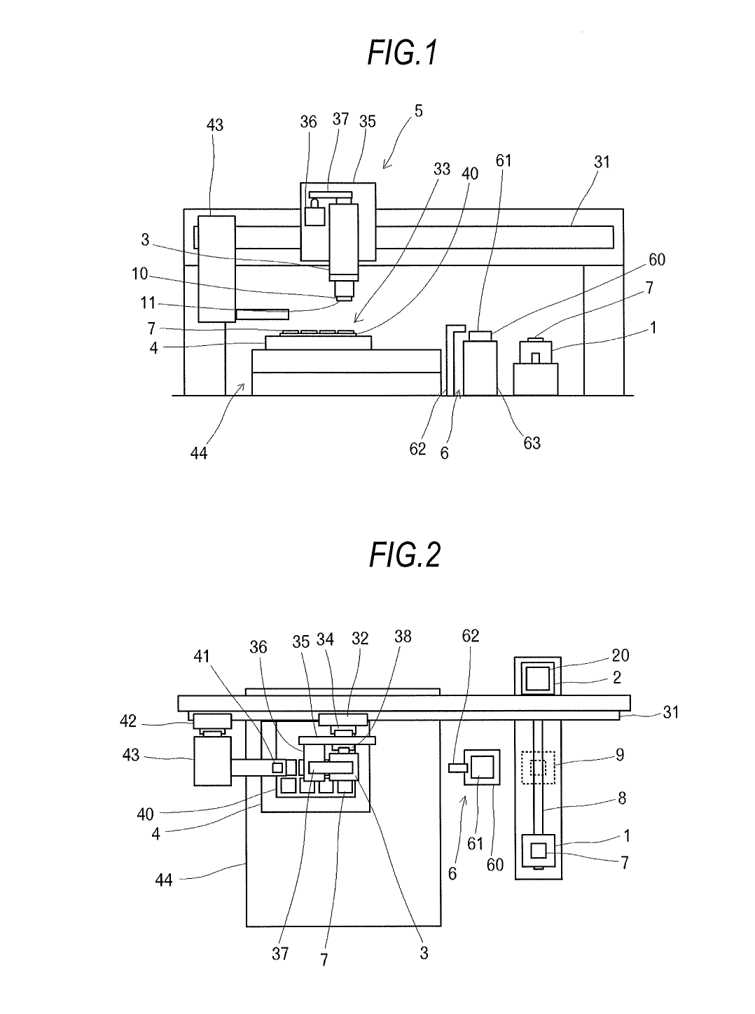

Hereinafter, embodiments of the invention will be described with reference to the drawings. FIG. 1 is a schematic explanatory front view of a bonding apparatus, and FIG. 2 is a schematic explanatory plan view of a bonding apparatus. In the drawings, a bonding apparatus includes a chip stage 1 that configures a chip supply unit, a flux stage 2, a bonding head 3, a bonding stage 4, a head movement unit 5, and a cooling unit 6.

The chip stage 1 is a stage on which a chip 7 is arranged, and is movably mounted on a Y-axis movement rail 8 that configures a Y-axis movement mechanism in Y-axis direction (upward/downward direction in FIG. 1). In FIG. 1, the reference numeral “1” denotes the chip stage, and the position of the chip stage I is the position to which the chip 7 is transferred by a pick & placer (not illustrated), and a dotted-line position provided on the lower side around a X-axis movement rail 31 (to be described later) on the Y-axis movement rail is a chip supply position 9.

Further, the reference numeral “2” in FIG. 1 denotes the flux stage on which a flux tray for applying flux onto the chip 7 that is arranged on the chip stage 1 is arranged. By positioning the chip stage 1 in the chip supply position, supplying the chip 7 from the chip stage 1 to the bonding head 3, and then moving the chip stage 1 from the chip supply position 9 to a position to which the chip 7 is transferred, the flux stage 2 is substantially simultaneously positioned in the chip supply position 9. Meanwhile, the bonding head 3 waits on the upper side of the chip supply position 9, and when the flux stage 2 is positioned in the chip supply position 9, the bonding head 3 descends to apply the flux on the back surface of the chip 7 through dipping only the back surface of the maintained chip 7 into the flux in the flux tray 20.

First and second embodiments of the bonding head 3 may be regarded depending on the difference in heating method. In the first embodiment, the bonding head 3 adopts an indirect heating method for indirectly heating the chip 7 through heating the bonding tool 10. In the second embodiment, the bonding head 3 adopts a direct heating method for directly heating the chip 7. Here, the bonding head 3 according to the first embodiment will be described. The bonding head 3 according to the first embodiment includes a bonding tool 10 having a suction surface 11 formed thereon to suck and maintain the chip 7, a suction portion 12 of the bonding tool 10, and a heating portion 21 heating the bonding tool 10 for bonding. The suction portion 12 is arranged below the heating portion 21, and the bonding tool 10 is maintained on the suction portion 12. On the suction surface 11 of the bonding tool 10, a chip suction hole C is formed to maintain the suction of the chip 7.

The suction portion 12 of the bonding tool 10 is a ring-shaped member having an inner space 13 A tool suction pipe 14 and a chip suction pipe 15 are formed on a casing 16 of the suction portion 12. Further, a tool base 18 is screw-fixed to the lower end of the casing 16 through a mask 17 by a tool base fixture 19. A tool suction hole A for sucking the bonding tool 10 is formed on the tool base 18.

The tool suction pipe 14 is connected to a vacuum source (not illustrated) and is configured to generate a vacuum suction force in the tool suction hole A and to make the bonding tool 10 suck the tool base 18 by the suction force. Further, during the operation of the bonding apparatus, the suction is always performed.

Separately from the tool suction hole A, a chip suction hole B is formed on the tool base 18. One side of the chip suction hole B of the tool base 18 is in succession with the chip suction hole C of the bonding tool 10, and the other side thereof communicates with the inner space 13 in which the chip suction pipe 15 is formed. By connecting the chip suction pipe 15 to the vacuum source (not illustrated) at a desired time, the vacuum suction force is generated in the chip suction hole C of the bonding tool 10 to make the bonding tool 10 suck and maintain the chip 7.

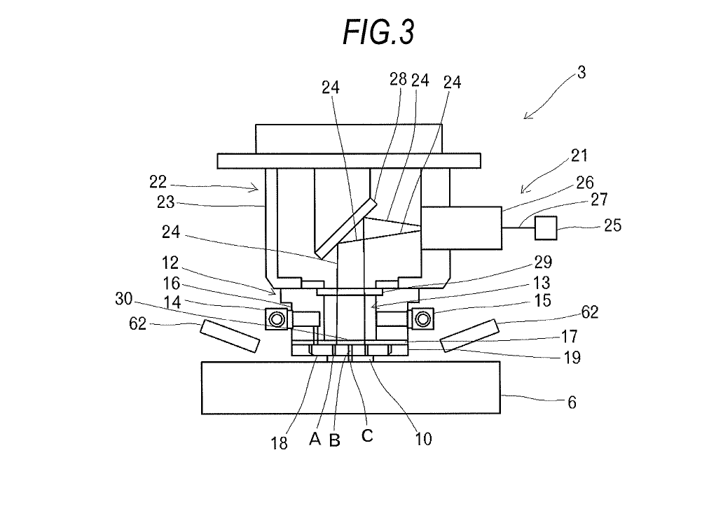

As illustrated in FIG. 3, the heating portion 21, which is configured to heat the bonding tool 10, is provided with a laser resonator 25 configured to oscillate laser beam 24, an irradiation barrel 26 that is a light guide unit guiding the laser beam 24 oscillated by the laser resonator 25 in the bonding head 3 according to the first embodiment, and a light receiving portion 22 receiving the laser beam 24 in the bonding head 3 according to the first embodiment and irradiating the bonding tool 10 with the laser beam 24. Further, the laser resonator 25 is a semiconductor laser configured to send near-infrared laser beam. In this embodiment, the heating portion 21 uses a laser heating method. However, the heating portion 21 may use other heating methods in the related art, e.g., a heating method by a ceramic heater.

In the casing 23 of the light receiving portion 22, a mirror 28 is installed such that the reflection direction of the mirror 28 is directed to the bonding tool 10 that is below the mirror 28 at an inclination angle. Further, a glass plate 29 is mounted between an empty portion in the casing 23 of the light receiving portion 22 and the inner space 13 of the suction portion 12 that is arranged below the empty portion.

The laser beam 24 that is oscillated from the laser resonator 25 is irradiated from an optical fiber 27 to the mirror 28 of the light receiving portion 22 through the irradiation barrel 26. The laser beam 24, of which the angle can be changed by the mirror 28, reaches the bonding tool 10 through the glass plate 29, a mask opening 30, and the tool base 18 to heat the bonding tool 10. The tool base 18 of the bonding head according to the first embodiment is made of quartz glass, which is a transparent material that the laser beam 24 can penetrate.

The bonding head 3 includes an X-axis movement mechanism, a lifting mechanism, and a θ-axis movement mechanism (rotation mechanism) as head movement unit. The X-axis movement mechanism has an X-axis movement rail 31 and an X-slider 32. The bonding head 3 is movable on the X-axis movement rail 31 through the X-slider 32 in the X-axis direction (left/right direction in FIGS. 1 and 2). By the X-axis movement mechanism, the bonding head 3 reciprocates between the chip supply position 9 on the chip stage 1 and a bonding position 33 on the bonding stage 4.

The lifting mechanism of the bonding head 3 is configured in a manner that a head base 35 is attached to a base slider 34 that is liftably mounted on the X-slider 32, and the bonding head 3 is mounted on the head base 35 through a load control device. Further, the bonding head 3 has a 0-axis movement mechanism (not illustrated), and can correct the posture of the chip 7 in the 0-axis direction (rotation direction).

The load control device of the bonding head 3 is configured by attaching the bonding head 3 to the head slider 38 that is mounted on the head base 35 to be movable upward/downward and including an arm 37 that is adhered to the bonding head 3 and a load cell 36 that is in contact with the arm 37. That is, the load control during the bonding is performed by the load cell 36.

Specifically, when the head base 35 descends at the bonding position 33, the chip 7 that is maintained by the bonding tool 10 comes in contact with the substrate 40 to restrict the descending of the bonding head 3. Until the time point of contact, the whole weight of the bonding head 3 is applied to the load cell 36 through the arm 37.

Further, when the head base descends, the load that is applied from the arm 37 to the load cell 36 falls out. That is, the load that is applied before the chip 7 comes in contact with the substrate 40 (the self-weight of the bonding head 3) is decreased, and the load as much as the decreased amount is applied to the substrate 40. Specifically, if the displayed value of the load cell 36 is 25N in the case where the load by the self-weight of the bonding head 3 is 30N, the difference of 5N becomes the load that is being applied to the substrate 40. Through this, the load is controlled with an appropriate value.

On the X-axis movement rail 31, a slider 42 for a camera is movably mounted in the X-axis direction (left/right direction in FIGS. 1 and 2), and a lifting body 43, which is movable upward/downward, is attached to the slider 42 for a camera. Further, a camera 41 as an imaging unit is attached to the lifting body 43. The camera 41 can simultaneously take images on upper and lower sides in order to acquire position information of the chip 7 and the bonding position 33 on the substrate 40.

The substrate 40 for bonding is arranged on the bonding stage 4, and bonding the chip 7 on the bonding position 33 of the substrate 40 is performed by heating the bonding tool 10 in the bonding position 33 on the bonding stage 4. The bonding stage 4 is installed on an XY-stage 44 that is movable in the X-axis direction by the X-axis movement mechanism and in the Y-axis direction by the Y-axis movement mechanism.

A cooling stage 60 configures a cooling unit 6 is arranged between the chip stage 1 and the bonding stage 4. The cooling stage 60 has an upper surface that is a cooling surface 61 and is configured to cool the bonding tool 10 by making the suction surface 11 of the bonding tool 10 come in contact with the cooling surface 61. In the embodiment, the cooling stage 60 has a Peltier element configured to cool the cooling surface 61 so as to compulsorily cool the bonding tool 10. In the embodiment, the cooling stage 60 is mounted with the Peltier element. Alternatively, a pipe for circulating cooling fluid may be arranged inside the bonding tool 10 instead of the Peltier element.

Further, the cooling stage 60 includes a gas supply device 62 configured to supply dew condensation prevention gas. By making the suction surface 11 of the bonding tool 10 come in contact with the cooling surface 61 of the cooling stage 60 in the dew condensation prevention gas atmosphere in which the gas supply device 62 supplies the gas, the dew condensation on the cooling surface 61 is prevented. Due to the dew condensation on the cooling surface 61, rust occurs in each place of the cooling unit 6 to reduce the lifespan of the device. Further, if droplets of dew condensation are attached to the suction surface 11, dust is attached to the inside of the device to pollute the chip 7, and this may cause malfunction for bonding. The gas supply device 62 prevents such dew condensation from occurring.

Further, the contact of the bonding tool 10 with the cooling stage 60 for cooling is made by the lifting mechanism on the side of the bonding tool 10, specifically, the upward/downward movement of the head base to which the bonding head 3 is attached. Alternatively, a lifting unit for lifting the cooling stage 60 may be put on the base 63 of the cooling unit 6, and the cooling surface 61 may be made to come in contact with the suction surface 11 of the bonding tool 10 by lifting the cooling stage 60 in a state where the bonding head 3 is stopped on the upper side of the cooling stage 60.

Hereinafter, the operation of the bonding apparatus according to the embodiment will be described. After the chip 7 is arranged on the chip stage 1 by the pick & placer (not illustrated), the chip supply unit moves the chip stage 1 to the chip supply position 9. When the chip stage 1 is moved from the chip supply position 9 to the position where the chip 7 is transferred after the chip 7 is supplied from the chip stage 1 to the bonding head 3, the flux stage 2 is substantially simultaneously positioned in the chip supply position 9. Meanwhile, the bonding head 3 waits on the upper side of the chip supply position 9, and when the flux stage 2 is positioned in the chip supply position 9, the bonding head 3 descends to apply the flux on the back surface of the chip 7 through dipping only the back surface of the maintained chip 7 into the flux in the flux tray 20.

Thereafter, the bonding head 3 is moved to the upper side of the bonding position 33, and the camera 41 is positioned between the chip 7 and the bonding position 33 on the substrate 40 to acquire respective position information. Further, based on the position information, the chip 7 and the substrate 40 are aligned to match their positions. That is, the posture of the chip 7 in the θ-axis direction is corrected by the θ-axis movement mechanism of the bonding head 3, and the position of the substrate 40 in the X-axis direction and the position of the substrate 40 in the Y-axis direction are corrected by the XY-stage 44 of the bonding stage 4.

When the position is determined, the bonding head 3 descends until the load indicated in the load cell 36 becomes a predetermined load, and by heating the bonding tool 10 through oscillation of the laser beam 24, the chip 7 is heated and the bump is melted to perform the bonding of the chip 7 on the substrate 40.

When the laser beam 24 is supplied for a predetermined time, the suction of the chip 7 is released to make the bonding head 3 secede from the bonding position 33. Next, the bonding head 3 moves to the upper side of the cooling surface 61 of the cooling stage 60, which is the cooling position, and descends to make the suction surface 11 of the bonding tool 10 come in contact with the cooling surface 61. At this time, by supplying dry air or a nitrogen gas having a low dew point through a nozzle of the gas supply device 62, the cooling surface 61 is prevented from condensing dew.

After the suction surface 11 of the bonding head comes in contact with the cooling surface 61 for a predetermined time, the bonding head 10 is made to secede from the cooling position and to move to the chip supply position 9 again to suck the next chip 7.

According to the heating method in the bonding head 3 according to the first embodiment, the chip 7 is indirectly heated by heating the bonding tool 10 through irradiation of the bonding tool 10 with the laser beam 24. Incidentally, if the chip 7 has high heat resistance, the chip 7 may be directly irradiated with the laser beam 24 like the bonding head according to the second embodiment.

In the case of the direct heating type bonding head, the bonding tool 10 of the bonding head 3 according to the first embodiment is omitted, and the chip 7 is maintained by the chip suction hole B of the tool base 18. That is, in the bonding head according to the second embodiment, the tool base 18 that is the transparent material becomes the bonding tool on which the suction surface that sucks and maintains the chip is formed. Since the heat is transferred from the directly heated chip 7 to the tool base 18, this case also requires cooling through the cooling unit 6.

According to such a direct heating method, in comparison to the indirect heating method of the bonding head 3 according to the first embodiment, work time can be reduced as for the time to increase the temperature of the bonding tool 10.

What is claimed is:

1. A bonding apparatus comprising:
a bonding head comprising a bonding tool, on which a suction surface for sucking and maintaining a chip is formed, and a heating unit;
a chip supply unit configured to supply the chip to the bonding tool;
a bonding stage on which a substrate is arranged;
a head movement unit configured to move the bonding head between a chip supply position by the chip supply unit and a bonding position on the bonding stage; and
a cooling unit configured to cool the bonding tool,
wherein the bonding apparatus is configured to:
supply the chip from the chip supply position to the bonding tool;
perform bonding of the chip on the substrate through heating the chip in the bonding position; and then
cool the bonding tool by the cooling unit,
wherein the cooling unit has a cooling surface configured to come in contact with the suction surface of the bonding tool, and
wherein the cooling unit is configured to cool the bonding tool through making the cooling surface come in contact with the suction surface.

2. The bonding apparatus according to claim 1,
wherein the cooling unit comprises a Peltier element for cooling the cooling surface and is configured to compulsorily cool the bonding tool.

3. The bonding apparatus according to claim 1,
wherein the cooling unit comprises a gas supply unit for supplying a dew condensation prevention gas and is configured to make the suction surface come in contact with the cooling surface in a dew condensation prevention gas atmosphere.

4. The bonding apparatus according to claim 1,
wherein the heating unit comprises:
a laser resonator configured to oscillate laser beam; and
a light guide unit configured to guide the laser beam generated by the laser resonator into the bonding head,
wherein the heating unit is configured to:
directly heat the chip by the laser beam that is oscillated from the laser resonator and is guided into the bonding head by the light guide unit; or
indirectly heat the chip through heating the bonding tool by the laser beam.
